(19) United States
(12) Patent Application Publication
(10) Pub. No.: US 2007/0032385 A1
(43) Pub. Date: Feb. 8, 2007

(54) Sustainable chemical processes

(76) Inventors: Joshua R. Dunetz, Jupiter, FL (US); Rocco P. Ciccolini, Newark, NJ (US); Jefferson W. Tester, Hingham, MA (US); Rick L. Danheiser, Watertown, MA (US)

Correspondence Address: HAMILTON, BROOK, SMITH & REYNOLDS, P.C., 530 VIRGINIA ROAD, P.O. BOX 9133, CONCORD, MA, 01742-9133, US

(21) Appl. No.: 11/471,272

(22) Filed: Jun. 20, 2006

Related U.S. Application Data
(60) Provisional application No. 60/692,185, filed on Jun. 20, 2005.

(51) Int. Cl. H01L 39/24

(52) U.S. Cl. 505/501

(57) ABSTRACT

A method includes preparing a protected amine compound represented by the following structural formula: 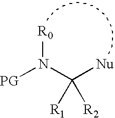
wherein the dotted line - - - is a covalent bond or no bond. The method includes the step of, in the presence of superatmospheric CO₂: a) intermolecularly reacting an iminium compound with a nucleophile Nu represented by the following structural diagram: 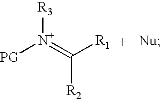
or b) intramolecularly reacting an iminium group of an iminium compound represented by the following structural formula, the iminium compound having a nucleophile: 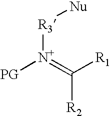 with the nucleophile of the iminium compound, thereby forming the protected amine compound.

### RELATED APPLICATION

This application claims the benefit of U.S. Provisional Application No. 60/692,185, filed on Jun. 20, 2005, the entire teachings of which are incorporated herein by reference.

### BACKGROUND OF THE INVENTION

Supercritical carbon dioxide (scCO₂) has attracted considerable attention in recent years as an alternative to conventional solvents for organic synthesis. This interest has been motivated by environmental and health considerations, as carbon dioxide is relatively nontoxic and nonflammable, inexpensive and widely available, and typically poses minimal problems with regard to waste disposal. The tunable solvent properties of scCO₂ have also attracted interest, as relatively small changes in temperature and pressure can often allow for significant changes in viscosity, density, and self-diffusivity. The successful application of scCO₂ as a reaction solvent for some synthetic transformations is now well documented. The rates and selectivities of Diels-Alder and dipolar cycloadditions in scCO₂ have been reported, as well as the development of protocols for effecting several Pd-catalyzed reactions in carbon dioxide. Other useful transformations that can be achieved in this “green” solvent include a number of oxidation reactions, catalytic hydrogenation, olefin metatheses, and enzyme-catalyzed organic reactions.

To date, however, only a few examples have been reported of carbon-nitrogen bond formation in scCO₂, principally due to the facility of the reaction of amines with this electrophilic solvent (vide infra).

The Pictet-Spengler reaction is an important method for the synthesis of isoquinoline and indole alkaloids. The valuable medicinal properties associated with tetrahydroisoquinolines and tetrahydro-β-carbolines continues to fuel interest in the synthesis of these classes of heterocycles. In the Pictet-Spengler reaction, these ring systems are produced via the cyclization of iminium ions generated in situ by the condensation of aldehydes with β-arylethylamines. Attempts to achieve Pictet-Spengler reactions in scCO₂ have been unsuccessful. For example, reaction of amine 1 with formaldehyde using scCO₂ led to a mixture of oligomeric products and none of the desired tetrahydroisoquinoline:

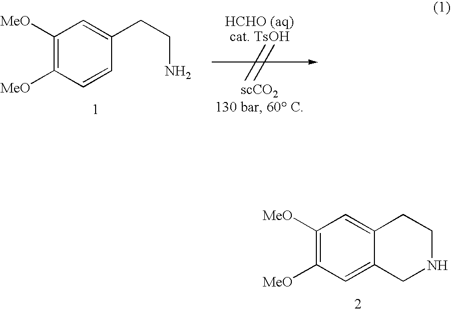

This result was not surprising, as it is well-documented that nucleophilic amines react with carbon dioxide to form carbamic acids of type 4 and ammonium carbamate salts of type 5 (eq 2).

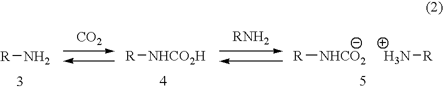

In the presence of scCO₂, amine 1 is thus intercepted prior to reaction with the aldehyde, and subsequent condensation of 4 and 5 with HCHO leads to the formation of the observed oligomeric products.

The reactivity of CO₂ toward basic amines poses a significant challenge that complicates the application of many nitrogen-heterocycle forming reactions in scCO₂. Thus, there is a need in the art for general strategies for the utilization of amines (and amine derivatives) in scCO₂, and and for the application of these strategies in C—N bond-forming reactions and the synthesis of nitrogen heterocycles.

### SUMMARY OF THE INVENTION

Disclosed herein are methods for enabling Pictet-Spengler cyclization in the presence of CO₂, particularly multiphasic scCO₂/CO₂-expanded liquid media. Moreover, these methods for conducting this important reaction in scCO₂ can be applicable to other C—N bond-forming processes as well.

In one embodiment, the invention is directed to a method for preparing a protected amine compound represented by structural formula (I): 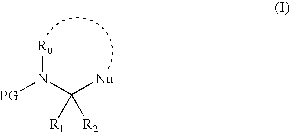
wherein the dotted line - - - is a covalent bond or no bond. The method includes the step of, in the presence of superatmospheric CO₂: intermolecularly reacting an iminium compound represented by structural formula (II) with a nucleophile represented as “Nu,” as shown below: 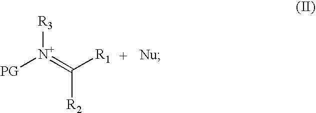
or, intramolecularly reacting an iminium group of an iminium compound represented by structural formula (III), the iminium compound having a nucleophile Nu, with the nucleophile Nu of the iminium compound: 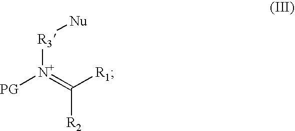
thereby forming the protected amine compound.

In structural formulas (I)-(III), R₀ is R₃ or R₃′; PG is an amine protecting group; R₁, R₂, and R₃ are each independently —H or an optionally substituted aliphatic, cycloaliphatic, nonaromatic heterocyclic, aryl, heteroaryl, aralkyl, or heteroaralkyl group, or R₁ and R₂, taken together with the C═O to which they are bonded, form a cycloaliphatic or nonaromatic heterocyclic ring; and R₃′ is an optionally substituted aliphatic, cycloaliphatic, nonaromatic heterocyclic, aryl, heteroaryl, aralkyl, or heteroaralkyl group.

In another embodiment, the invention is directed to a method of forming an iminium intermediate compound represented by structural formula (V): 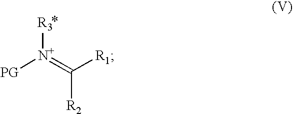
including reacting, in the presence of an acid and superatmospheric CO₂, a protected amine compound represented by PG—NHR₃* with a carbonyl compound represented by structural formula (VI): 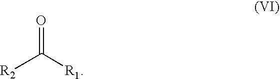
wherein R₁, R₂, R₃, and R₃′ and R₃* each have the values given above, and R₃* is R₃ or R₃′—Nu, wherein Nu is the nucleophile.

The disclosed methods allow the reaction of amines with nucleophiles in green solvents such as CO₂, including supercritical CO₂. In particular, the methods can lead to C—N bond formation, for example, the C—N bond formation in the intramolecular cyclization of the Pictet Spengler reaction.

### BRIEF DESCRIPTION OF THE DRAWINGS

FIG. 1 is a synthetic scheme for in situ protection of amines and cyclization using the methods of the invention.

FIG. 2 depicts a carbamate synthesis reaction, which is specific embodiment of the invention, and lists various conditions for the carbamate synthesis reaction in Table 1.

FIG. 3 depicts side products from one specific embodiment of the invention, a reaction of amine compound 1 with dimethyl carbonate (DMC) in the presence of scCO₂ (Ar=3,4-dimethoxyphenyl).

FIG. 4 depicts another specific embodiment of the invention, a tetrahydroquinoline synthesis reaction, and lists various conditions for the tetrahydroquinoline synthesis in Table 2.

FIG. 5 is a synthetic scheme for yet another specific embodiment of the invention, synthesis of tetrahydro-β-carbolines at conditions: (a) 5 equiv CO(OBn)₂, scCO₂, 130 degrees C., 130 bar, 24 h; (b) add 1.3 equiv aq HCHO, 1.3 equiv 50% aq trifluoracetic acid (TFA), 80 degrees C., 160 bar, 24 h.

FIG. 6 is a picture of a Thar stainless steel view cell reactor that can be employed in the invention.

FIG. 7 is a schematic representation of a reactor that can be employed in the invention.

### DETAILED DESCRIPTION OF THE INVENTION

The foregoing will be apparent from the following more particular description of example embodiments of the invention, as illustrated in the accompanying drawings. The drawings are not necessarily to scale, emphasis instead being placed upon illustrating embodiments of the present invention.

The claimed reactions of the methods of the invention typically can be conducted in situ in the presence of CO₂ during reactions of the methods of the invention. Typically, the CO₂ is in an amount or partial pressure that is superatmospheric, i.e., an amount or partial pressure greater than that of the atmosphere. Typically, the partial pressure of the CO₂ is greater than 1, 5, 25, 50, or 75 atmospheres (bar). In some embodiments, the partial pressure of CO₂ is between about 80 bar and about 200 bar, more typically between about 90 and 195 bar such as between 95 and 100 bar, between 120 and 130 bar, or between 180 and 190 bar. The temperature can be from about 0 degrees C. to about 300 degrees C., typically from about 50 to about 200 degrees C., more typically from about 100 to about 150 degrees C., or in some embodiments about 130 degrees C. Generally, the CO₂ can be at a temperature and pressure within the supercritical range of its phase diagram.

In some embodiments, the dotted line - - - in the protected amine compound can be a covalent bond, and the protected amine compound and the free amine compound are represented respectively by structural formulas (VII) and (VIII):

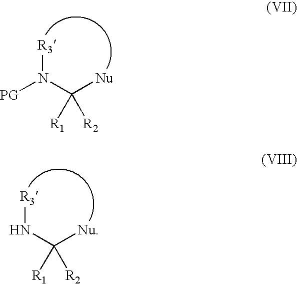

In some embodiments, the dotted line - - - in the protected amine compound can be no bond, and the protected amine compound and the free amine compound are represented respectively by structural formulas (IX) and (X): 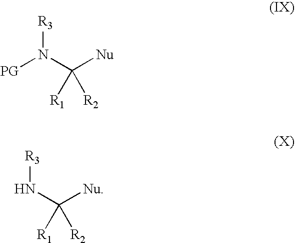
The nucleophile Nu can be any nucleophile that is reactive with an amine, e.g. the protected amine. Typically, Nu can be selected from an optionally substituted alkene, cycloalkene, diene, cyclodiene, aryl, or heteroaryl.

In various embodiments, the iminium compound can be prepared in situ by reacting, in the presence of an acid, a second protected amine compound represented by PG—NHR₃* with a carbonyl compound represented by structural formulas (VI):

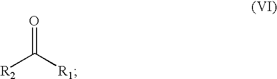

wherein R₃* is R₃ or R₃′—Nu. The acid can be any strong mineral or organic acid that does not otherwise react with the compounds. For example, typical acids include hydrochloric, trifluoroacetic, sulfuric, and the like.

The protecting group PG can be any amine protecting group known to the art, such as a steric protecting group or an electronic protecting group. The protecting group renders the second protected amine less reactive to the CO₂ compared to an unprotected amine represented by H—NHR₃*. Typically, protecting groups are well known to the art and are given in Greene, Wuts, “Protecting Groups in Organic Synthesis”, the entire teachings of which are incorporated herein by reference. In various embodiments, PG can be selected from optionally substituted alkoxycarbonyl, alkanoyl, aryloxycarbonyl, aroyl, aryl, aralkyl, alkylsilyl, arylsilyl, and aralkylsilyl.

Typically, the second protected amine can be prepared by reacting a precursor of the protecting group with the unprotected amine. In some embodiments, the second protected amine is prepared by reacting an optionally substituted dialkyl carbonate with the unprotected amine.

In various embodiments, the unprotected amine can be represented by R₅—R₄—NH₂, wherein R₄ is an optionally substituted linker selected from one to four membered alkylene or two to four membered heteroalkylene; and R₅ is an optionally substituted ring selected from phenyl, naphthyl, tetrahydronaphthyl, anthracyl, imidazolyl, isoimidazolyl, thienyl, furanyl, pyridyl, pyrimidyl, pyranyl, pyrazolyl, pyrrolyl, pyrazinyl, thiazolyl, isothiazolyl, oxazolyl, isooxazolyl, 1,2,3-triazolyl, 1,2,4-triazolyl, tetrazolyl, benzo[1,3]dioxolyl, 2,3-dihydro-benzo[1,4]dioxine, benzopyrimidyl, benzopyrazyl, benzofuranyl, indolyl, benzothienyl, benzoxazolyl, benzoisooxazolyl, benzothiazolyl, benzoisothiazolyl, quinolinyl, isoquinolinyl, benzimidazolyl, tetrahydroquinolinyl, and tetrahydroisoquinolinyl.

In some embodiments, the protected amine compound can be represented by a structural formula selected from: 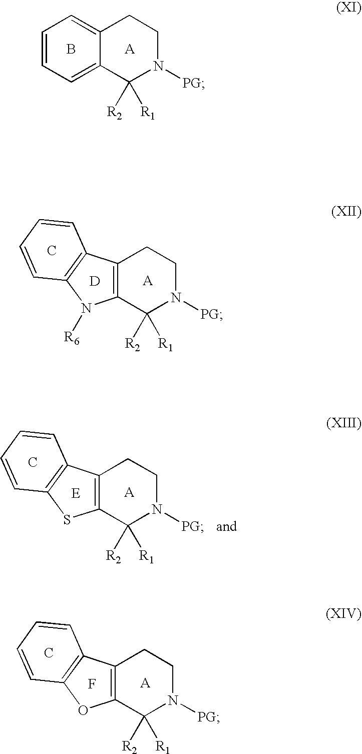
wherein Rings A, B, C, D, E, and F are optionally substituted; R₆ is —H or an optionally substituted aliphatic, cycloaliphatic, nonaromatic heterocyclic, aryl, heteroaryl, aralkyl, or heteroaralkyl group, or an amine protecting group; and PG is an amine protecting group. Examples of PG, R₁ and R₂ are the same as those described above.

In a particular embodiment, PG is alkyloxycarbonyl (e.g. methyloxy carbonyl), aryloxycarbonyl (e.g. benzyloxy carbonyl) or aralkoxycarbonyl.

In another particular embodiment, R₁ is —H.

In yet another particular embodiment, R₂ is —H, phenyl, ethyl, isopropyl, alkoxycarbonyl, aryloxycarbonyl, aralkoxycarbonyl, or an optionally substituted aliphatic, cycloaliphatic, nonansmatic heterocyclic, aryl, heteroaryl, aralkyl, or heteroaralkyl group. In a more particular embodiment, R₂ is —H, phenyl, C1-C4 alkyl, such as ethyl, propyl (e.g., 2-propyl) or butyl (e.g., n-butyl or 2-butyl), or —CO₂—C1-C4 alkyl), such as —CO₂—CH₃, or —CO₂—C₂H₅

Exemplification

The invention relates to strategies for suppressing reaction between CO₂ and an amine without interfering with the ability of the amine to participate in the desired C—N bond-forming reactions. In some specific embodiments, the disclosed invention is drawn to protecting amines as their less nucleophilic carbamate derivatives are surprisingly inert to CO₂ yet reactive to nucleophiles, e.g., in the Pictet-Spengler heterocyclization reaction (see, for example, J. R. Dunetz, et al. Chem. Comuun., 2005, 4465-4467, the entire teachings of which are incorporated herein by reference). Particularly desirable can be the prospect of converting amine substrates to carbamates in situ, thus utilizing CO₂ as both a reagent and solvent for the reaction. However, alkyl halides and tin reagents can be unattractive from an environmental point of view. It is now found that carbonates such as dimethyl carbonate (DMC) can be employed as a “green methylating agent” for the in situ conversion of amines to methyl carbamates in CO₂ as formulated in eq 3 (R¹═Me).

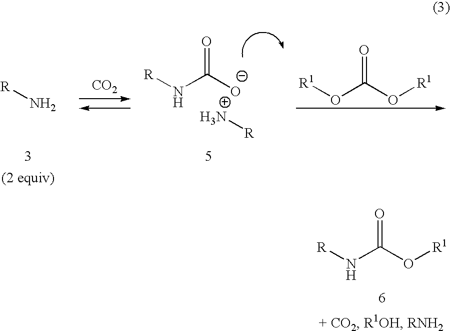

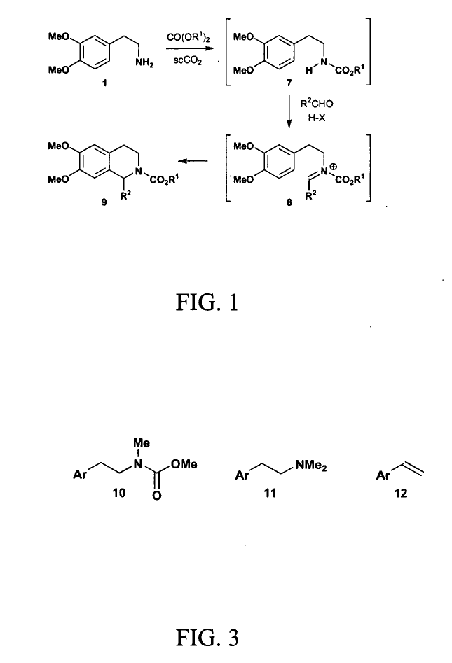

FIG. 1 outlines the application of this synthetic strategy for effecting reactions of amines in CO₂ in the context of the Pictet-Spengler reaction. Reaction of 1 with CO₂ can generate an ammonium carbamate salt, which upon alkylation with DMC can produce the carbamate 7. Condensation with an aldehyde (in the presence of acid) can then furnish the iminium ion intermediate 8, which can undergo cyclization to afford the desired Pictet-Spengler product. An added benefit of this approach can be that N-acyliminium ions such as 8 are known to exhibit enhanced reactivity in Pictet-Spengler cyclizations.

Reactions were carried out in a Thar stainless steel view cell reactor (25 mL internal volume) that allows visual inspection via two coaxial sapphire windows. Cell pressure and temperature were monitored with a pressure gauge and internal thermocouple probe. Temperature set-points were achieved using a controller interfaced with insulated heating tape wrapped tightly about the exterior cell wall. Reactor contents were mixed using a magnetic stir bar.

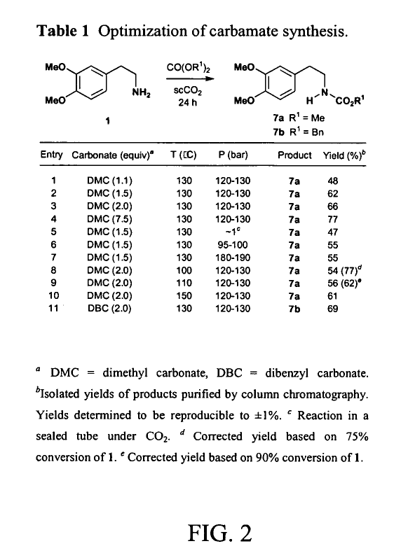

Table 1 of FIG. 2 summarizes the results of optimization of conditions for the in situ generation of carbamates 7a and 7b from 1. In a typical reaction, a biphasic system forms consisting of lower density supercritical-like CO₂ phase and a higher density CO₂-rich liquid phase, the latter containing dialkyl carbonate and the ammonium carbamate salt derived from reaction of 1 with CO₂. After 24 h at 130° C., complete conversion of 1 was observed leading in quantitative yield to a mixture of 7a and the side products 10, 11, and 12 (FIG. 3). Thus, an issue was to maximize the alkylation of the intermediate carbamate salt 5 (leading to the desired product) relative to the competing N-alkylation of the amine starting material (which was shown to be responsible for the formation of these side products).

The equilibrium formulated in eq 2 is expected to be shifted further toward 5 with an increase in the concentration of CO₂ in the CO₂-expanded liquid phase, leading to an increase in the selectivity for alkylation of the carbamate salt 5 over alkylation of amine 3. Dimethyl carbonate readily absorbs carbon dioxide, and so an increase in the amount of DMC employed can result in an increase in the amount of CO₂ in the liquid DMC/ammonium carbamate salt phase. This can lead to an increase in selectivity for the desired alkylation, and thus an improved yield of 7a, as shown in Table 1, entries 1 to 4. The concentration of MeOH byproduct, which was shown to lower the selectivity for carbamate formation, was also reduced when more DMC was employed. Improved yields of 7a were also observed with increasing CO₂ pressure, which similarly promoted carbamate salt formation via an increase in liquid phase CO₂ concentration (compare entries 2, 5, and 6). It is noteworthy that the selectivity for 7a decreased at very high pressures (entry 7) where the DMC partitioned from the liquid phase into the blanket scCO₂ phase, resulting in a smaller volume of DMC in the liquid phase (verified visually), and thus a lower concentration of CO₂ in this phase. Selectivity for 7a over 10-12 increased at lower temperatures (entry 8), possibly due to (a) increased absorption of CO₂ into the liquid phase at lower temperatures, and/or (b) slower N-methylation of the amine at temperatures ≦100° C. However, alkylation of the ammonium carbamate salt was also sluggish at 100° C. resulting in incomplete conversion after 24 h. Finally, entry 11 demonstrates that this strategy for the in situ protection of amines in scCO₂ can also be extended to the formation of benzyl carbamates by substituting dibenzyl carbonate (DBC) for DMC. The utility of Cbz derivatives as protective groups for amines is well established.

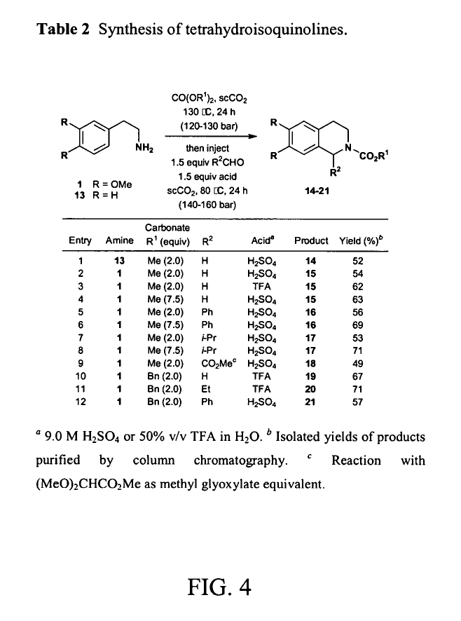

The in situ generated carbamates were employed as substrates for acyl-Pictet-Spengler reactions in a triphasic system consisting of a supercritical-like CO₂ phase, a CO₂-rich liquid phase, and a H₂O-rich liquid phase. Table 2 of FIG. 4 delineates the scope of this two-stage strategy for effecting Pictet-Spengler reactions of β-arylethylamines. Typical conditions involved treating the amine with dialkyl carbonate in scCO₂ at 130° C. (120-130 bar) for 24 h, cooling the resulting reaction mixture to 80° C., and then adding the aldehyde and acid (1.5 equiv) via a pressurized injection loop. Further reaction at 80° C. for 24 h then afforded the desired tetrahydroisoquinolines. Both electron-neutral and electron-rich β-arylethylamines participated in the reaction, which could also be applied to a variety of aliphatic and aromatic aldehydes. Pictet-Spengler reaction with methyl glyoxylate could be achieved by introducing this aldehyde in the form of its dimethyl acetal derivative. Trifluoroacetic acid could be employed in place of H₂SO₄ to promote iminium ion formation, and its use lead to somewhat improved yields probably due to the sensitivity of some carbamate groups to sulfuric acid under these conditions. Finally it was noted that the overall yield for this two-stage process improves somewhat as the volume of DMC increases from 2.0 to 7.5 equiv relative to amine. It is believed that this effect was attributed to improved selectivity for carbamate formation over N-methylation as discussed above.

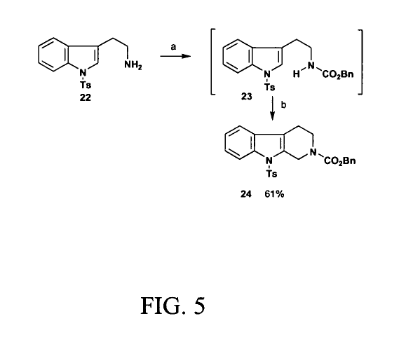

FIG. 5 illustrates the extension of the Pictet-Spengler reaction in multiphasic scCO₂/CO₂-expanded liquid media to include the synthesis of tetrahydro-β-carbolines. Reaction of tryptamine 22 with CO₂ and DBC afforded 23 which reacted with formaldehyde in the presence of TFA to fumish 24 in 61% overall yield.

In summary, the disclosed methods, employing the in situ conversion of the amine substrate, e.g., β-arylethylamine reactants, to protected derivatives, e.g., carbamate derivatives by reaction with CO₂ and dialkyl carbonates, can effect Pictet-Spengler reactions in multiphasic scCO₂/CO₂-expanded liquid media. This general strategy for utilizing amines can be employed in other C—N bond-forming reactions in environmentally-friendly media by employing appropriate substrates and nucleophiles.

General Procedures

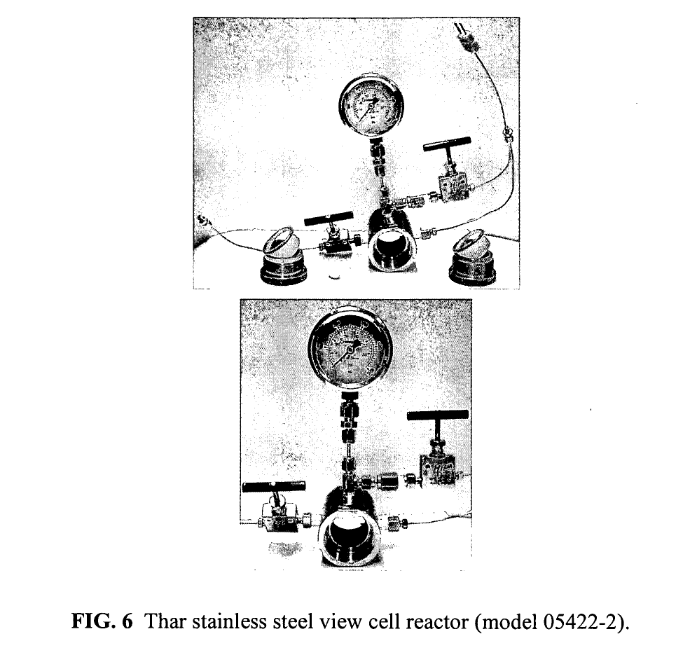

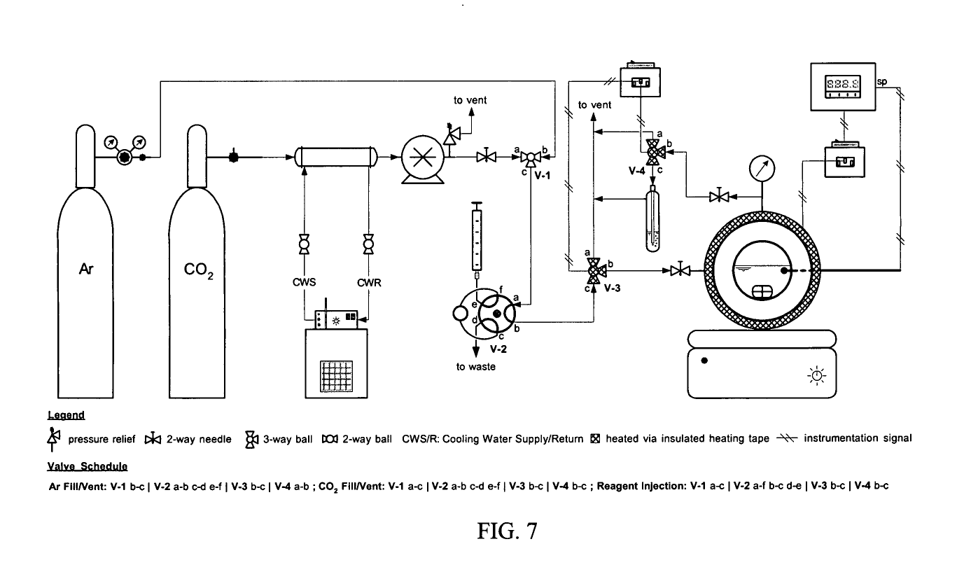

All reactions were performed in the 25-mL Thar stainless steel view cell reactor (model 05422-2) shown in FIG. 6. A schematic flow diagram of the experimental apparatus is in FIG. 7. This reactor allows visual inspection via two 1-inch coaxial sapphire windows. Cell pressures and temperatures were monitored with a Swagelok industrial pressure gauge (0-350 bar range, accuracy of ±5 bar) and Omega K-type low-noise thermocouple probe (accuracy of ±1° C.). Temperature set-points were attained using an Omega miniature autotune temperature controller in PID mode (series CN9000A) in conjunction with a Powerstat variable autotransformer (type 3PN116B) and Omega insulated heating tape (model# STH051-060) wrapped tightly about the exterior cell wall. The reactor was purged with argon before pressurizing with CO₂ and the reactor contents were mixed using a magnetic stir bar. Reaction product solutions and chromatography fractions were concentrated by rotary evaporation at ca. 20 mmHg and then at ca. 0.1 mmHg (vacuum pump) unless otherwise indicated. Thin layer chromatography was performed on Merck precoated glass-backed silica gel 60 F-254 0.25 mm plates. Column chromatography was performed on EM Science silica gel 60 or Silicycle silica gel 60 (230-400 mesh).

Materials

Commercial grade reagents were used without further purification except as indicated below. Isobutyraldehyde and propionaldehyde were distilled under argon. Carbon dioxide (99.9995%) was purchased from Airgas. Aqueous solutions of H₂SO4 and TFA were prepared by adding the acid to deionized water.

Instrumentation

The melting points of crystalline products were determined with a Fisher-Johns melting point apparatus and are uncorrected. Infrared spectra were obtained using a Perkin Elmer 2000 FT-IR spectrophotometer. ¹H NMR and ¹³C NMR spectra were measured with an Inova 500 spectrometer. ¹H NMR chemical shifts are expressed in parts per million (δ) downfield from tetramethylsilane (with the CHCl₃ peak at 7.27 ppm used as a standard). ¹³C NMR chemical shifts are expressed in parts per million (δ) downfield from tetramethylsilane (with the central peak of CHCl₃ at 77.23 ppm used as a standard). Low resolution mass spectra (GC-MS) were measured on a Agilent 6890N series gas chromatograph with Agilent 5973 series mass selective detection. High resolution mass spectra (HRMS) were measured on a Bruker Daltonics APEXII 3 telsa Fourier transform mass spectrometer.

General Procedure A for the Two-Stage Reaction Using Sulfuric Acid to Promote Pictet-Spengler Cyclization. N-(Methoxycarbonyl)-1,2,3,4-Tetrahydroisoquinoline (14)

A 25-mL, stainless steel Thar view cell reactor was charged with phenethylamine (13) (1.6 mL, 1.5 g, 13 mmol) and dimethyl carbonate (2.2 mL, 2.4 g, 26 mmol), pressurized to 50 bar with CO₂, heated to 130° C., and then pressurized with additional CO₂ to 120 bar. The biphasic reaction mixture was stirred at 130° C. (120-130 bar) for 24 h. The reactor was allowed to cool to 80° C. and formaldehyde (1.5 mL, 13 M in H₂O, 20 mmol) and H₂SO₄ (2.0 mL, 9.0 M in H₂O, 18 mmol) were added sequentially via the 2-mL sample loop (depicted in FIG. 7 as #9). The resulting triphasic reaction mixture was stirred at 80° C. (140-160 bar) for 24 h. The reactor was cooled to room temperature, the CO₂-phase was sparged into a biphasic mixture containing 15 mL of CH₂Cl₂ and 15 mL of water, and the remaining reactor contents were dissolved in 100 mL of CH₂Cl₂ and 100 mL of water. The aqueous layer was separated from the combined organic layers and extracted with three 75-mL portions of CH₂Cl₂. The combined organic layers were washed with 150 mL of satd NaCl solution, dried over MgSO₄, filtered, and concentrated to afford 1.925 g of a dark yellow oil. Column chromatography on 90 g of silica gel (gradient elution with 10-15% EtOAc-hexanes) provided 1.271 g (52%) of tetrahydroisoquinoline 14 as a colorless oil: IR (neat) 2953, 1709, 1605, and 1449 cm⁻¹; ¹H NMR (FIG. 10) (500 MHz, CDCl₃) δ7.10-7.32 (m, 4H), 4.63 (br s, 2H), 3.76 (s, 3H), 3.70 (m, 2H), and 2.86 (br s, 2H); ¹³C NMR (125 MHz, CDCl₃) δ156.2, 134.6 (and rotamer 134.8), 133.3 (and rotamer 133.6), 128.8 (and rotamer 129.0), 128.7, 126.5, 126.4 (and rotamer 126.7), 52.9, 45.9, 41.5 (and rotamer 41.7), and 28.9 (and rotamer 29.2); GC-MS m/z: 191 (M⁺).

N-(Methoxycarbonyl)-6,7-dimethoxy-1,2,3,4-tetrahydroisoquinoline (15)

Reaction of amine 1 (2.1 mL, 2.3 g, 13 mmol), DMC (2.1 mL, 2.2 g, 25 mmol), formaldehyde (1.5 mL, 13 M in H₂O, 20 mmol) and H₂SO₄ (2.0 mL, 9.0 M in H₂O, 18 mmol) according to General Procedure A afforded 3.291 g of a dark brown oil. Column chromatography on 120 g of silica gel (gradient elution with 5-50% EtOAc-hexanes) provided 1.710 g (54%) of tetrahydroisoquinoline 15 as a colorless oil: IR (neat) 2953, 1710, 1691, 1612, and 1513 cm⁻¹; ¹H NMR (FIG. 11) (500 MHz, CDCl₃) δ6.61 (s, 1H), 6.58 (m, 1H), 4.54 (br s, 2H), 3.85 (s, 3H), 3.84 (s, 3H), 3.74 (s, 3H), 3.65-3.70 (m, 2H), and 2.76 (br s, 2H); ¹³C NMR (125 MHz, CDCl₃) δ155.9, 147.53, 147.49, 126.0 (and rotamer 126.3), 124.7 (and rotamer 125.1), 111.3 (and rotamer 111.4), 108.8 (and rotamer 109.0), 55.82, 55.79, 52.5, 45.3, 41.3 (and rotamer 41.5), and 28.1 (and rotamer 28.3); GC-MS m/z: 251 (M⁺).

N-(Methoxycarbonyl)-6,7-dimethoxy-1-phenyl-1,2,3,4-tetrahydroisoquinoline (16)

Reaction of amine 1 (2.1 mL, 2.3 g, 13 mmol), DMC (2.1 mL, 2.2 g, 25 mmol), benzaldehyde (2.0 mL, 2.1 g, 20 mmol) and H₂SO₄ (2.0 mL, 9.0 M in H₂O, 18 mmol) according to General Procedure A afforded 4.150 g of a brown oil. Column chromatography on 140 g of silica gel (elution with 30% EtOAc-hexanes) provided 2.300 g (56%) of tetrahydroisoquinoline 16 as a white solid: mp 98-100° C.; IR (film) 2952, 1703, 1692, 1611, 1515, and 1444 cm⁻¹; ¹H NMR (FIG. 12) (500 MHz, CDCl₃) δ7.24-7.31 (m, 5H), 6.67 (s, 1H), 6.50 (s, 1H), 6.41 (rotamer, br s, 0.5H), 6.24 (rotamer, br s, 0.5H), 4.15 (rotamer, br s, 0.5H), 4.00 (rotamer, br s, 0.5H), 3.89 (s, 3H), 3.76 (s, 6H), 3.15 (br s, 1H), 2.94 (br s, 1H), 2.69 (rotamer, br s, 0.5H), and 2.66 (rotamer, br s, 0.5H); ¹³C NMR (125 MHz, CDCl₃) δ156.0, 148.2, 147.6, 142.7, 128.8, 128.7, 128.4, 127.6, 127.1, 111.3, 111.2, 57.3 (and rotamer 57.4), 56.12, 56.06, 52.9, 37.7 (and rotamer 37.9), and 28.0 (and rotamer 28.2); GC-MS m/z: 327 (M⁺).

N-(Methoxycarbonyl)-1-isopropyl-6,7-dimethoxy-1,2,3,4-tetrahydroisoquinoline (17)

Reaction of amine 1(2.1 mL, 2.3 g, 13 mmol), DMC (2.1 mL, 2.2 g, 25 mmol), isobutyraldehyde (1.7 mL, 1.3 g, 19 mmol) and H₂SO₄ (2.0 mL, 9.0 M in H₂O, 18 mmol) according to General Procedure A afforded 2.882 g of a dark orange oil. Column chromatography on 160 g of silica gel (gradient elution with 20-30% EtOAc-hexanes) provided 1.975 g (53%) of tetrahydroisoquinoline 17 as a colorless oil: IR (neat) 2958, 1698, 1611, 1518, and 1446 cm⁻¹; ¹H NMR (FIG. 13) (500 MHz, CDCl₃) δ6.52-6.56 (m, 2H), 4.70 (rotamer, d, J=8.5 Hz, 0.5H), 4.57 (rotamer, d, J=8.5 Hz, 0.5H), 4.02 (rotamer, app quint, J=6.1 Hz, 0.5H), 3.76 (s, 6H), 3.61 (s, 3H), 3.38 (rotamer, dt, J=13.0, 6.9 Hz, 0.5H), 3.29 (rotamer, ddd, J=5.8, 8.9, 13.1 Hz, 0.5H), 2.78 (m, 0.5H), 2.66-2.71 (m, 2H), 1.92 (m, 1H), and 0.84-0.91 (m, 6H); ¹³C NMR (125 MHz, CDCl₃) δ156.3 (and rotamer 156.6), 147.5 (and rotamer 147.6), 146.49 (and rotamer 146.53), 128.5 (and rotamer 129.0), 126.1 (and rotamer 126.3), 111.3 (and rotamer 111.4), 111.0 (and rotamer 111.1), 60.1 (and rotamer 60.2), 55.79 (and rotamer 55.83), 55.7, 52.3 (and rotamer 52.4), 39.0 (and rotamer 39.5), 33.77 (and rotamer 33.81), 27.1 (and rotamer 27.4), 20.1 (and rotamer 20.2), and 19.5 (and rotamer 19.6); GC-MS m/z: 293 (M⁺).

N-(Methoxycarbonyl)-6,7-dimethoxy-1-methoxycarbonyl-1,2,3,4-tetrahydroisoquinoline (18)

Reaction of amine 1 (2.1 mL, 2.3 g, 13 mmol), DMC (2.1 mL, 2.2 g, 25 mmol), methyl dimethoxyacetate (2.3 mL, 2.5 g, 19 mmol) and H₂SO₄ (2.0 mL, 9.0 M in H₂O, 18 mmol) according to General Procedure A afforded 2.910 g of a dark red oil. Column chromatography on 140 g of silica gel (gradient elution with 30-35% EtOAc-hexanes) provided 1.901 g (49%) of tetrahydroisoquinoline 18 as a colorless oil: IR (neat) 2954, 1744, 1699, 1611, 1520, and 1447 cm⁻¹; ¹H NMR (FIG. 15) (500 MHz, CDCl₃) δ6.98 (rotamer, s, 0.5H), 6.96 (rotamer, s, 0.5H), 6.62 (s, 1H), 5.54 (rotamer, s, 0.5H), 5.47 (rotamer, s, 0.5H), 4.00 (rotamer, dt, J=12.5, 5.5 Hz, 0.5H), 3.87 (s, 3H), 3.85 (s, 3H), 3.80 (rotamer, m, 0.5H), 3.76 (rotamer, s, 1.5H), 3.75 (rotamer, m, 0.5H), 3.74 (rotamer, s, 1.5H), 3.72 (rotamer, s, 1.5H), 3.71 (rotamer, s, 1.5H), 3.67 (rotamer, m, 0.5H), and 2.76-2.86 (m, 2H); ¹³C NMR (125 MHz, CDCl₃) δ171.8, 156.0 (and rotamer 156.6), 148.66 (and rotamer 148.70), 147.66 (and rotamer 147.69), 127.3 (and rotamer 127.5), 121.6 (and rotamer 122.1), 111.0 (and rotamer 111.2), 110.6 (and rotamer 110.8), 57.5 (and rotamer 57.6), 56.1, 55.9, 53.0 (and rotamer 53.1), 52.56 (and rotamer 52.59), 40.2 (and rotamer 40.5), and 28.0 (and 28.2); GC-MS m/z: 309 (M⁺).

General Procedure B for the Two-Stage Reaction Using Trifluoroacetic Acid to Promote Pictet-Spengler Cyclization. N-(Carbobenzyloxy)-6,7-dimethoxy-1,2,3,4-tetrahydroisoquinoline (19)

A 25-mL, stainless steel Thar view cell reactor was charged with amine 1 (2.1 mL, 2.3 g, 13 mmol) and dibenzyl carbonate (5.3 mL, 6.2 g, 26 mmol), pressurized to 50 bar with CO₂, heated to 130° C., and then pressurized with additional CO₂ to 120 bar. The biphasic reaction mixture was stirred at 130° C. (120-130 bar) for 24 h. The reactor was allowed to cool to 80° C. and formaldehyde (1.5 mL, 13 M in H₂O, 20 mmol) and trifluoroacetic acid (3.0 mL, 50% v/v in H₂O, 19 mmol) were added sequentially via the 3-mL sample loop (depicted in FIG. 7 as #9). The resulting triphasic reaction mixture was stirred at 80° C. (140-160 bar) for 24 h. The reactor was cooled to rt, the CO₂-phase was sparged into a biphasic mixture containing 15 mL of CH₂Cl₂ and 15 mL of water, and the remaining reactor contents were dissolved in 100 mL of CH₂Cl₂ and 100 mL of water. The combined organic and aqueous layers were washed with 100 mL of 1 M NaOH solution, and the aqueous layer was separated and extracted with four 75-mL portions of CH₂Cl₂. The combined organic layers were washed with 200 mL of satd NaCl solution, dried over MgSO₄, filtered, and concentrated to afford 8.528 g of a dark yellow oil. Column chromatography on 160 g of silica gel (gradient elution with 20-30% EtOAc-hexanes) provided 2.755 g (67%) of tetrahydroisoquinoline 19 as a colorless oil: IR (neat) 2935, 1703, 1692, 1611, 1517, and 1427 cm⁻¹; ¹H NMR (FIG. 16) (500 MHz, CDCl₃) δ7.25-7.36 (m, 5H), 6.58 (s, 1H), 6.56 (rotamer, br s, 0.5H), 6.51 (rotamer, br s, 0.5H), 5.15 (s, 2H), 4.54 (s, 2H), 3.79 (s, 3H), 3.78 (s, 3H), 3.67 (m, 2H), and 2.72 (m, ²H); ¹³C NMR (125 MHz, CDCl₃) δ155.1 (and rotamer 155.2), 147.42, 147.37, 136.5, 128.3, 127.8, 127.6, 125.9 (and rotamer 126.1), 124.4 (and rotamer 125.0), 111.2 (and rotamer 111.3), 108.7 (and rotamer 108.9), 66.8 (and rotamer 66.9), 55.64, 55.63, 45.1 (and rotamer 45.3), 41.2 (and rotamer 41.5), and 28.0 (and rotamer 28.2); HRMS-ESI m/z: [M+Na]⁺calcd for C₁₉H₂₁NO₄, 350.1363; found, 350.1360.

N-(Carbobenzyloxy)-1-ethyl-6,7-dimethoxy-1,2,3,4-tetrahydroisoquinoline (20)

Reaction of amine 1 (2.1 mL, 2.3 g, 13 mmol), DBC (5.3 mL, 6.2 g, 26 mmol), propionaldehyde (1.4 mL, 1.1 g, 19 mmol) and TFA (3.0 mL, 50% v/v in H₂O, 19 mmol) according to General Procedure B afforded 8.890 g of an orange oil. Column chromatography on 140 g of silica gel (gradient elution with 10-30% EtOAc-hexanes) provided 3.173 g (71%) of tetrahydroisoquinoline 20 as a colorless oil: IR (neat) 2963, 1693, 1611, 1519, and 1427 cm⁻¹; ¹H NMR (FIG. 17) (500 MHz, CDCl₃) δ7.33-7.38 (m, 5H), 6.62 (rotamer, s, 0.5H), 6.60 (rotamer, s, 0.5H), 6.58 (rotamer, s, 0.5H), 6.56 (rotamer, s, 0.5H), 5.23 (rotamer, d,J=12.5 Hz, 0.5H), 5.18 (rotamer, s, 1H), 5.09 (rotamer, d, J=12.5 Hz, 0.5H), 5.07 (rotamer, t, J=7.3 Hz, 0.5H), 4.97 (rotamer, t, J=7.3 Hz, 0.5H), 4.28 (rotamer, m, 0.5H), 4.09 (rotamer, m, 0.5H), 3.86 (s, 6H), 3.33 (rotamer, m, 0.5H), 3.22 (rotamer, m, 0.5H), 2.93 (rotamer, m, 0.5H), 2.85 (rotamer, m, 0.5H), 2.67 (rotamer, m, 0.5H), 2.64 (rotamer, m, 0.5H), 1.80 (m, 2H), 1.00 (rotamer, t, J=7.3 Hz, 1.5H), and 0.96 (rotamer, t, J=7.3 Hz, 1.5H); ¹³C NMR (125 MHz, CDCl₃) δ155.2, 147.2 (and rotamer 147.3), 147.0, 136.4 (and rotamer 136.6), 129.2 (and rotamer 129.5), 128.0, 127.48 (and rotamer 127.6), 127.3 (and rotamer 127.55), 125.3 (and rotamer 125.5), 111.0 (and rotamer 111.2), 109.5 (and rotamer 109.8), 66.5 (and rotamer 66.8), 55.5, 55.4, 55.3, 37.0 (and rotamer 37.7), 29.2 (and rotamer 29.4), 27.4 (and rotamer 27.8), and 10.68 (and rotamer 10.72); HRMS-ESI m/z: [M+Na]⁺calcd for C₂₁H₂₅NO₄, 378.1676; found, 378.1666.

N-(Carbobenzyloxy)-6,7-dimethoxy-1-phenyl-1,2,3,4-tetrahydroisoquinoline (21)

Reaction of amine 1 (2.1 mL, 2.3 g, 13 mmol), DBC (5.3 mL, 6.2 g, 26 mmol), benzaldehyde (2.0 mL, 2.1 g, 18 mmol) and H₂SO₄ (2.0 mL, 9.0 M in H₂O, 18 mmol) according to General Procedure A afforded 8.960 g of an orange oil. Column chromatography on 100 g of silica gel (gradient elution with 5-30% EtOAc-hexanes) provided 2.882 g (57%) of tetrahydroisoquinoline 21 as a very pale yellow oil: IR (neat) 2935, 1693, 1611, 1517, and 1425 cm⁻¹; ¹H NMR (500 MHz, CDCl₃) δ7.17-7.40 (m, 10H), 6.68 (s, 1H), 6.53 (s, 1H), 6.45 (rotamer, br s, 0.5H), 6.26 (rotamer, br s, 0.5H), 5.22-5.30 (m, 1H), 5.18 (rotamer, s, 0.5H), 5.16 (rotamer, s, 0.5H), 4.20 (rotamer, br s, 0.5H), 4.07 (rotamer, br s, 0.5H), 3.90 (s, 3H), 3.76 (s, 3H), 3.19 (br s, 1H), 2.96 (br s, 1H), and 2.69 (br s, 1H); ¹³C NMR (125 MHz, CDCl₃) δ154.9 (and rotamer 155.3), 147.9, 147.4, 142.4, 136.6, 128.5, 128.4, 128.3, 128.2, 127.7 (and rotamer 127.9), 127.4, 127.0, 126.7 (and rotamer 126.8), 126.6, 110.9 (and rotamer 111.2), 67.1 (and rotamer 67.4), 57.1 (and rotamer 57.3), 55.8, 55.7, 37.6 (and rotamer 37.8), and 27.8 (and rotamer 28.0); HRMS-ESI m/z: [M+Na]⁺calcd for C₂₅H₂₅NO₄, 426.1676; found, 426.1683.

2-(Carbobenzyloxy)-9-(p-toluenesulfonyl)-1,2,3,4-tetrahydro-β-carboline (24)

A 25-mL, stainless steel Thar view cell reactor was charged with tryptamine 22 (0.798 g, 2.54 mmol) and DBC (2.7 mL, 3.2 g, 13 mmol), pressurized to 50 bar with CO₂, heated to 130° C., and then pressurized with additional CO₂ to 130 bar. The biphasic reaction mixture was stirred at 130° C. (130 bar) for 24 h. The reactor was allowed to cool to 80° C. and formaldehyde (0.50 mL, 6.8 M in H₂O, 3.4 mmol) and TFA (0.50 mL, 50% v/v in H₂O, 3.2 mmol) were added sequentially via the 0.50-mL sample loop (depicted in FIG. 7 as #9). The resulting triphasic reaction mixture was stirred at 80° C. (160 bar) for 24 h. The reactor was cooled to rt, the CO₂-phase was sparged into a biphasic mixture containing 15 mL of CH₂Cl₂ and 15 mL of water, and the remaining reactor contents were dissolved in 100 mL of CH₂Cl₂ and 50 mL of water. The combined organic and aqueous layers were washed with 50 mL of satd NaHCO₃ solution, and the aqueous layer was separated and extracted with three 50-mL portions of CH₂Cl₂. The combined organic layers were dried over MgSO₄, filtered, and concentrated to afford 4.116 g of a yellow oil. Two successive purifications by column chromatography on 120 g of silica gel (5-20% EtOAc-hexanes) provided 0.715 g (61%) of tetrahydro-β-carboline 24 as a white solid: mp 52-55° C.; IR (film) 2922, 1704, 1597, 1426, 1366, and 1232 cm⁻¹; ¹H NMR (FIG. 18) (500 MHz, CDCl₃) 58.16 (d, J=8.2 Hz, 1H), 7.79 (m, 1H), 7.64 (m, 1H), 7.32-7.44 (m, 7H), 7.21-7.28 (m, 2H), 7.02 (m, 1H), 5.23 (s, 2H), 5.02 (br s, 2H), 3.81 (br s, 2H), 2.73 (br s, 2H), 2.33 (rotamer, s, 1H), and 2.30 (rotamer, s, 2H); ¹³C NMR (125 MHz, CDCl₃) δ155.6 (and rotamer 155.7), 145.1, 136.7, 135.5 (and rotamer 136.2), 131.0 (and rotamer 131.6), 130.1, 129.6, 128.7, 128.3, 128.1, 126.5 (and rotamer 126.7), 124.7 (and rotamer 124.8), 123.6 (and rotamer 123.7), 118.4 (and rotamer 118.5), 117.1 (and rotamer 117.8), 114.4, 67.6, 43.5 (and rotamer 43.8), 41.2 (and rotamer 41.4), 21.7, and 21.2; HRMS-ESI m/z: [M+Na]⁺calcd for C₂₆H₂₄N₂O₄S, 483.1349; found, 483.1355.

### EQUIVALENTS

While this invention has been particularly shown and described with references to preferred embodiments thereof, it will be understood by those skilled in the art that various changes in form and details may be made therein without departing from the scope of the invention encompassed by the appended claims.

What is claimed is:

1. A method of forming a protected amine compound represented by structural formula (I): 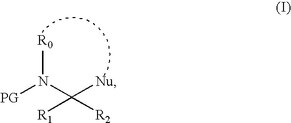
comprising the step of, in the presence of superatmospheric CO₂:
a) intermolecularly reacting an iminium compound represented by structural formula (II) with a nucleophile represented as Nu: 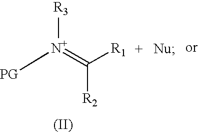
b) intramolecularly reacting an iminium group of an iminium compound represented by structural formula (III), the iminium compound having a nucleophile: 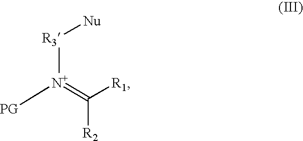
with the nucleophile of the iminium compound, thereby forming the protected amine compound, wherein:
PG is an amine protecting group;
R₀ is R₃ or R₃′;
R₁, R₂ and R₃ are each independently —H or an optionally substituted aliphatic, cycloaliphatic, nonaromatic heterocyclic, aryl, heteroaryl, aralkyl, or heteroaralkyl group, or R₁ and R₂, taken together with the C═O to which they are bonded, form a cycloaliphatic or nonaromatic heterocyclic ring;
R₃′ is an optionally substituted aliphatic, cycloaliphatic, nonaromatic heterocyclic, aryl, heteroaryl, aralkyl, or heteroaralkyl group; and
- - - is a covalent bond or no bond.

2. The method of claim 1, wherein the partial pressure of the CO₂ is greater than 1 atmosphere.

3. The method of claim 1, wherein the CO₂ is supercritical.

4. The method of claim 1, wherein the amine compound is represented by structural formula (VII):

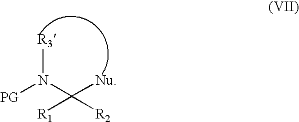

5. The method of claim 1, wherein the amine compound is represented by structural formula (IX):

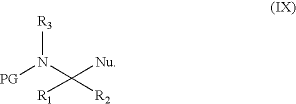

6. The method of claim 1, wherein Nu is a nucleophile selected from an optionally substituted alkene, cycloalkene, diene, cyclodiene, aryl, or heteroaryl.

7. The method of claim 6, wherein the iminium compound is prepared in situ by reacting, in the presence of an acid, a second protected amine compound represented by PG—NHR₃* with a carbonyl compound represented by structural formula (VI): 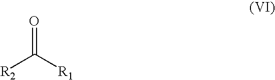
wherein R₃* is R₃ or R₃_40 —Nu

8. The method of claim 7, wherein PG is a steric protecting group or an electronic protecting group, the second protected amine being less reactive to the CO₂ compared to an unprotected amine represented by H—NHR₃*.

9. The method of claim 8, wherein PG is selected from optionally substituted alkoxycarbonyl, alkanoyl, aryloxycarbonyl, aroyl, aryl, aralkyl, alkylsilyl, arylsilyl, and aralkylsilyl.

10. The method of claim 9, wherein the second protected amine is prepared in situ in the CO₂.

11. The method of claim 10, wherein the second protected amine is prepared by reacting a precursor of the protecting group with the unprotected amine.

12. The method of claim 1 1, wherein the second protected amine is prepared by reacting an optionally substituted dialkyl carbonate and carbon dioxide with the unprotected amine.

13. The method of claim 11, wherein the unprotected amine is represented by R₅—R₄—NH₂, wherein:
R₄ is an optionally substituted linker selected from one to four membered alkylene or two to four membered heteroalkylene; and
R₅ is an optionally substituted ring selected from phenyl, naphthyl, tetrahydronaphthyl, anthracyl, imidazolyl, isoimidazolyl, thienyl, furanyl, pyridyl, pyrimidyl, pyranyl, pyrazolyl, pyrrolyl, pyrazinyl, thiazolyl, isothiazolyl, oxazolyl, isooxazolyl, 1,2,3-triazolyl, 1,2,4-triazolyl, tetrazolyl, benzo[1,3]dioxolyl, 2,3-dihydro-benzo[1,4]dioxine, benzopyrimidyl, benzopyrazyl, benzofuranyl, indolyl, benzothienyl, benzoxazolyl, benzoisooxazolyl, benzothiazolyl, benzoisothiazolyl, quinolinyl, isoquinolinyl, benzimidazolyl, tetrahydroquinolinyl, and tetrahydroisoquinolinyl.

14. The method of claim 1, wherein the protected amine compound is represented by a structural formula selected from: 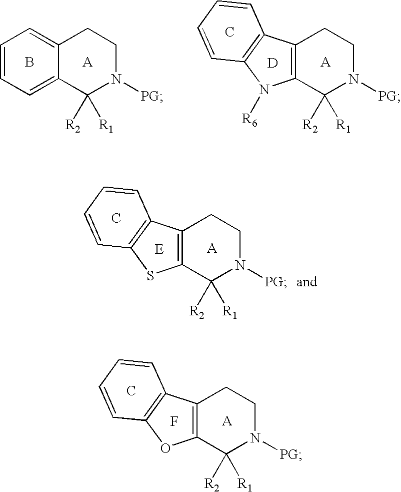
wherein:
Rings A, B, C, D, E, and F are optionally substituted; and
R₆ is —H or an optionally substituted aliphatic, cycloaliphatic, nonaromatic heterocyclic, aryl, heteroaryl, aralkyl, or heteroaralkyl group, or an amine protecting group.

15. The method of claim 14, wherein PG is alkoxycarbonyl, aryloxycarbonyl, or aralkoxycarbonyl.

16. The method of claim 15, wherein R₁ is —H.

17. The method of claim 15, wherein R₂ is —H or an optionally substituted alkoxycarbonyl, aryloxycarbonyl, aralkoxycarbonyl, aliphatic, cycloaliphatic, nonaromatic heterocyclic, aryl, heteroaryl, aralkyl, or heteroaralkyl group.

18. The method of claim 17, wherein R₂ is —H, phenyl, C—C4 alkyl or, —CO₂—(C1-C4 alkyl).

19. A method of forming an iminium compound represented by structural formula (V): 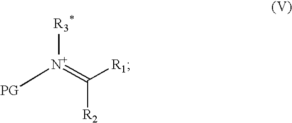
comprising the step of reacting, in the presence of an acid and superatmospheric CO₂, a protected amine compound represented by PG—NHR₃* with a carbonyl compound represented by structural formula (VI): 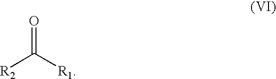
wherein:
PG is an amine protecting group;
R₃* is R₃ or R₃′—Nu, wherein Nu is a nucleophile;
R₁, R₂, and R₃ are each independently —H or an optionally substituted aliphatic, cycloaliphatic, nonaromatic heterocyclic, aryl, heteroaryl, aralkyl, or heteroaralkyl group, or R₁ and R₂, taken together with the C=O to which they are bonded, form a cycloaliphatic or nonaromatic heterocyclic ring; and
R₃′ is an optionally substituted aliphatic, cycloaliphatic, nonaromatic heterocyclic, aryl, heteroaryl, aralkyl, or heteroaralkyl group.

20. The method of claim 19, wherein the pressure of the CO₂ is greater than 1 atmosphere.

21. The method of claim 19, wherein the CO₂ is supercritical.

22. The method of claim 19, wherein Nu is a nucleophile selected from an optionally substituted alkene, cycloalkene, diene, cyclodiene, aryl, or heteroaryl.

23. The method of claim 19, wherein PG is a steric protecting group or an electronic protecting group, the protected amine being less reactive to the CO₂ compared to an unprotected amine represented by H—NHR₃*.

24. The method of claim 23, wherein PG is selected from optionally substituted alkoxycarbonyl, alkanoyl, aryloxycarbonyl, aroyl, aryl, aralkyl, alkylsilyl, arylsilyl, and aralkylsilyl.

25. The method of claim 24, further comprising protecting the unprotected amine in situ in the CO₂.

26. The method of claim 25, wherein the protected amine is prepared by reacting a precursor of the protecting group with the unprotected amine.

27. The method of claim 26, wherein the protected amine is prepared by reacting an optionally substituted dialkyl carbonate with the unprotected amine.
